(19) United States
(12) Patent Application Publication
(10) Pub. No.: US 2024/0145233 A1
(43) Pub. Date: May 2, 2024

(54) PROCESSING METHOD, METHOD OF MANUFACTURING SEMICONDUCTOR DEVICE, PROCESSING APPARATUS AND NON-TRANSITORY COMPUTER-READABLE RECORDING MEDIUM

(71) Applicant: Kokusai Electric Corporation, Tokyo (JP)

(72) Inventors: Daigo YAMAGUCHI, Toyama-shi (JP); Masaru KADOSHIMA, Toyama-shi (JP)

(73) Assignee: Kokusai Electric Corporation, Tokyo (JP)

(21) Appl. No.: 18/405,275

(22) Filed: Jan. 5, 2024

Related U.S. Application Data
(63) Continuation of application No. PCT/JP2021/030846, filed on Aug. 23, 2021.

(51) Int. Cl. H01L 21/02; C23C 16/52

(52) U.S. Cl. CPC H01L 21/02164; C23C 16/52; H01L 21/02167; H01L 21/0217; H01L 21/0228

(57) ABSTRACT

There is provided a technique that includes: (a) forming a non-flowable film on a surface of a substrate on which a recess is provided and an oxygen-containing film is exposed by supplying a first material to the substrate at a first temperature; and (b) forming a flowable film on the non-flowable film by supplying a second material to the substrate at a second temperature lower than the first temperature.

### CROSS-REFERENCE TO RELATED PATENT APPLICATION

This application is a bypass continuation application of PCT International Application No. PCT/JP2021/030846, filed on Aug. 23, 2021, in the WIPO, the entire contents of which are hereby incorporated by reference.

### BACKGROUND

### 1. Field

The present disclosure relates to a processing method, a method of manufacturing a semiconductor device, a processing apparatus and a non-transitory computer-readable recording medium.

### 2. Related Art

As a part of a manufacturing process of a semiconductor device, a process of forming a film on a substrate may be performed. In such a case, a process of forming a film with fluidity (hereinafter, also referred to as a “flowable film”) on the substrate provided with a concave portion (also referred to as a “recess”) on a surface thereof may be performed.

### SUMMARY

According to the present disclosure, there is provided a technique capable of improving characteristics of a film formed on a substrate provided with a recess on a surface thereof.

According to an aspect of the present disclosure, there is provided a technique that includes: (a) forming a non-flowable film on a surface of a substrate on which a recess is provided and an oxygen-containing film is exposed by supplying a first material to the substrate at a first temperature; and (b) forming a flowable film on the non-flowable film by supplying a second material to the substrate at a second temperature lower than the first temperature.

### BRIEF DESCRIPTION OF THE DRAWINGS

FIG. 1 is a diagram schematically illustrating a vertical cross-section of a vertical type process furnace of a substrate processing apparatus preferably used in embodiments of the present disclosure.

FIG. 2 is a diagram schematically illustrating a horizontal cross-section, taken along a line A-A shown in FIG. 1, of the vertical type process furnace of the substrate processing apparatus preferably used in the embodiments of the present disclosure.

FIG. 3 is a block diagram schematically illustrating a configuration of a controller and related components of the substrate processing apparatus preferably used in the embodiments of the present disclosure.

FIG. 4 is a flow chart schematically illustrating a substrate processing sequence according to a first embodiment of the present disclosure.

FIG. 5 is a flow chart schematically illustrating a substrate processing sequence according to a second embodiment of the present disclosure.

FIG. 6 is a flow chart schematically illustrating a substrate processing sequence according to a third embodiment of the present disclosure.

FIG. 7 is a diagram schematically illustrating an example of the present disclosure and a comparative example.

FIG. 8A is a diagram schematically illustrating a partially enlarged cross-section of a surface of a wafer according to the example of the present disclosure, and FIG. 8B is a diagram schematically illustrating a partially enlarged cross-section of a surface of a wafer according to the comparative example.

### DETAILED DESCRIPTION

### First Embodiment of Present Disclosure

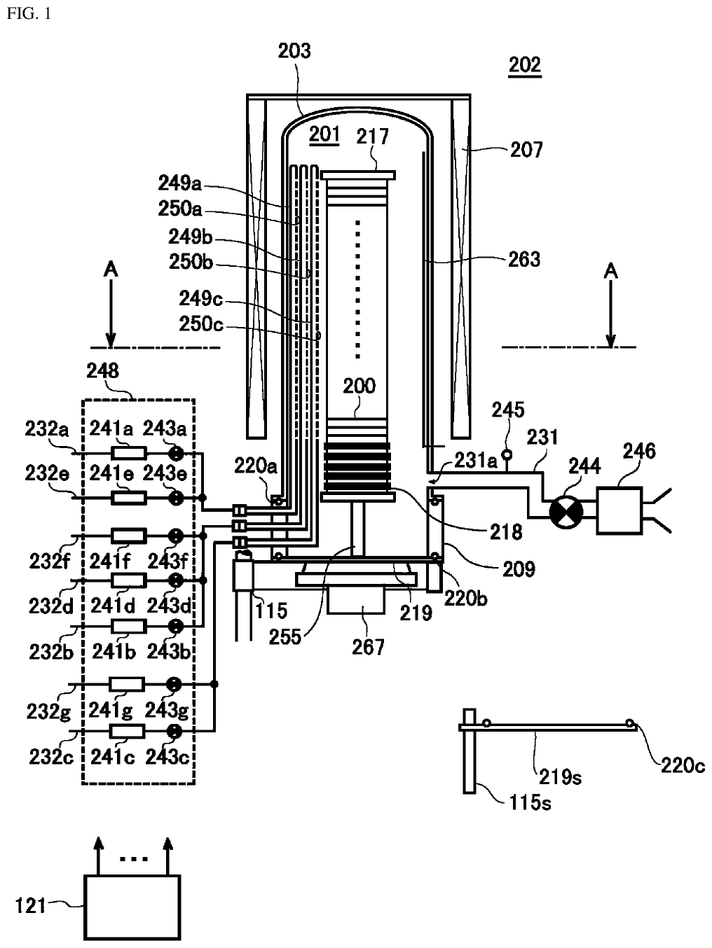

Hereinafter, one or more embodiments (also simply referred to as “embodiments”) of the technique of the present disclosure will be described in detail mainly with reference to FIGS. 1 through 4. First, a first embodiment of the technique of the present disclosure will be described in detail. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

(1) Configuration of Substrate Processing Apparatus

As shown in FIG. 1, a substrate processing apparatus according to the present embodiment includes a vertical type process furnace (also simply referred to as a “process furnace”) 202. The process furnace 202 includes a heater 207 serving as a heating structure or a heating system (which is a temperature regulator or a temperature adjusting structure). The heater 207 is of a cylindrical shape, and is vertically installed while being supported by a support plate (not shown). The heater 207 also functions as an activator (also referred to as an “exciter”) capable of activating (or exciting) a gas by a heat.

A reaction tube 203 is provided in an inner side of the heater 207 to be aligned in a manner concentric with the heater 207. For example, the reaction tube 203 is made of a heat resistant material such as quartz (SiO₂) and silicon carbide (SiC). For example, the reaction tube 203 is of a cylindrical shape with a closed upper end and an open lower end. A manifold 209 is provided under the reaction tube 203 to be aligned in a manner concentric with the reaction tube 203. For example, the manifold 209 is made of a metal material such as stainless steel (SUS). For example, the manifold 209 is of a cylindrical shape with open upper and lower ends. An upper end portion of the manifold 209 is engaged with a lower end portion of the reaction tube 203 so as to support the reaction tube 203. An O-ring 220a serving as a seal is provided between the manifold 209 and the reaction tube 203. Similar to the heater 207, the reaction tube 203 is installed vertically. A process vessel (also referred to as a “reaction vessel”) is constituted mainly by the reaction tube 203 and the manifold 209. A process chamber 201 is provided in a hollow cylindrical portion of the process vessel. The process chamber 201 is configured to be capable of accommodating a plurality of wafers including a wafer 200 serving as a substrate. Hereinafter, the plurality of wafers including the wafer 200 may also be simply referred to as “wafers 200”. The wafer 200 is processed in the process chamber 201.

Nozzles 249a, 249b and 249c are provided in the process chamber 201 so as to penetrate a side wall of the manifold 209. The nozzle 249a serves as a first supplier (which is a first supply structure), the nozzle 249b serves as a second supplier (which is a second supply structure) and the nozzle 249c serves as a third supplier (which is a third supply structure). The nozzle 249a may also be referred to as a “first nozzle 249a”, the nozzle 249b may also be referred to as a “second nozzle 249b” and the nozzle 249c may also be referred to as a “third nozzle 249c”. For example, each of the nozzles 249a, 249b and 249c may be made of a heat resistant material such as quartz and silicon carbide (SiC). Gas supply pipes 232a, 232b and 232c are connected to the nozzles 249a, 249b and 249c, respectively. The nozzles 249a, 249b and 249c are different nozzles. Each of the nozzles 249a and 249c are provided adjacent to the nozzle 249b.

Mass flow controllers (also simply referred to as “MFCs”) 241a, 241b and 241c serving as flow rate controllers (flow rate control structures) and valves 243a, 243b and 243c serving as opening/closing valves are sequentially installed at the gas supply pipes 232a, 232b and 232c, respectively, in this order from upstream sides to downstream sides of the gas supply pipes 232a, 232b and 232c in a gas flow direction. A gas supply pipe 232e is connected to the gas supply pipe 232a at a downstream side of the valve 243a of the gas supply pipe 232a. Gas supply pipes 232d and 232f are connected to the gas supply pipe 232b at a downstream side of the valve 243b of the gas supply pipe 232b. A gas supply pipe 232g is connected to the gas supply pipe 232c at a downstream side of the valve 243c of the gas supply pipe 232c. MFCs 241d, 241e, 241f and 241g and valves 243d, 243e, 243f and 243g are sequentially installed at the gas supply pipes 232d, 232e, 232f and 232g, respectively, in this order from upstream sides to downstream sides of the gas supply pipes 232d, 232e, 232f and 232g in the gas flow direction. For example, each of the gas supply pipes 232a through 232g is made of a metal material such as SUS.

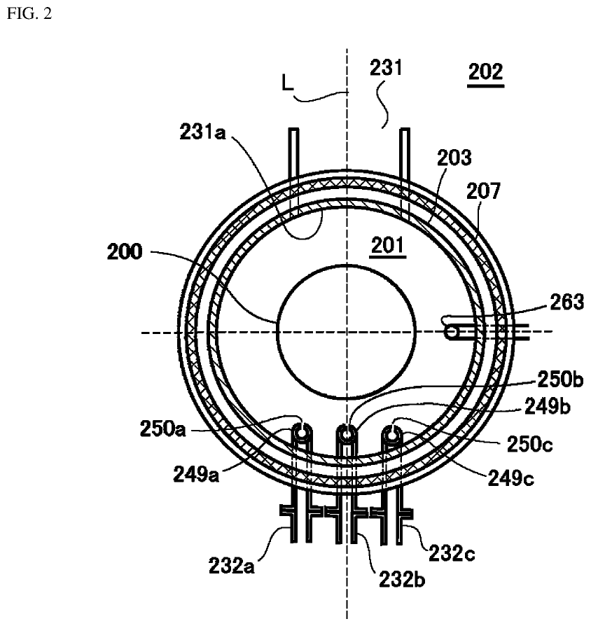

As shown in FIG. 2, each of the nozzles 249a through 249c is installed in an annular space provided between an inner wall of the reaction tube 203 and the wafers 200 when viewed from above, and extends upward from a lower portion toward an upper portion of the reaction tube 203 along the inner wall of the reaction tube 203 (that is, extends upward along a wafer arrangement direction). That is, each of the nozzles 249a through 249c is installed in a region that is located beside and horizontally surrounds a wafer arrangement region in which the wafers 200 are arranged (stacked) along the wafer arrangement region. When viewed from above, the nozzle 249b is arranged so as to face an exhaust port 231a described later along a straight line (denoted by “L” shown in FIG. 2) with a center of the wafer 200 transferred (loaded) into the process chamber 201 interposed therebetween. The nozzles 249a and 249c are arranged along the inner wall of the reaction tube 203 (that is, along an outer periphery of the wafer 200) such that the straight line L passing through the nozzle 249b and a center of the exhaust port 231a is interposed therebetween. The straight line L may also be referred to as a straight line passing through the nozzle 249b and the center of the wafer 200. That is, it can be said that the nozzle 249c is provided opposite to the nozzle 249a with the straight line L interposed therebetween. The nozzles 249a and 249c are arranged line-symmetrically with respect to the straight line L serving as an axis of symmetry. A plurality of gas supply holes 250a, a plurality of gas supply holes 250b and a plurality of gas supply holes 250c are provided at side surfaces of the nozzles 249a, 249b and 249c, respectively, such that gases are supplied via the gas supply holes 250a through the gas supply holes 250c, respectively. The gas supply holes 250a through the gas supply holes 250c are open to face the exhaust port 231a, when viewed from above, and are configured such that the gases are supplied toward the wafers 200 via the gas supply holes 250a through the gas supply holes 250c. The gas supply holes 250a through the gas supply holes 250c are provided from the lower portion toward the upper portion of the reaction tube 203.

A first source serving as a first material and a second source serving as a second material are supplied into the process chamber 201 through the gas supply pipe 232a provided with the MFC 241a and the valve 243a and the nozzle 249a.

A first reactant serving as the first material is supplied into the process chamber 201 through the gas supply pipe 232b provided with the MFC 241b and the valve 243b and the nozzle 249b.

A second reactant serving as the second material is supplied into the process chamber 201 through the gas supply pipe 232c provided with the MFC 241c and the valve 243c and the nozzle 249c.

A third reactant serving as the second material is supplied into the process chamber 201 through the gas supply pipe 232d provided with the MFC 241d and the valve 243d, the gas supply pipe 232b and the nozzle 249b.

That is, in the present specification, the first source and the first reactant may be collectively or individually referred to as the “first material”, and the second source, the second reactant and the third reactant may be collectively or individually referred to as the “second material”.

An inert gas is supplied into the process chamber 201 via the gas supply pipes 232e through 232g provided with the MFCs 241e through 241g and the valves 243e through 243g, respectively, the gas supply pipes 232a through 232c and the nozzles 249a through 249c. The inert gas acts as a purge gas, a carrier gas, a dilution gas and the like.

A first material supplier (which is a first material supply structure or a first material supply system) is constituted mainly by the gas supply pipes 232a and 232b, the MFCs 241a and 241b and the valves 243a and 243b. The first material supplier may include: a first source supplier (which is a first source supply structure or a first source supply system) constituted mainly by the gas supply pipe 232a, the MFC 241a and the valve 243a; and a first reactant supplier (which is a first reactant supply structure or a first reactant supply system) constituted mainly by the gas supply pipe 232b, the MFC 241b and the valve 243b. A second material supplier (which is a second material supply structure or a second material supply system) is constituted mainly by the gas supply pipes 232a, 232c and 232d, the MFCs 241a, 241c and 241d and the valves 243a, 243c, 243d. The second material supplier may include: a second source supplier (which is a second source supply structure or a second source supply system) constituted mainly by the gas supply pipe 232a, the MFC 241a and the valve 243a; a second reactant supplier (which is a second reactant supply structure or a second reactant supply system) constituted mainly by the gas supply pipe 232c, the MFC 241c and the valve 243c; and a third reactant supplier (which is a third reactant supply structure or a third reactant supply system) constituted mainly by the gas supply pipe 232d, the MFC 241d and the valve 243d. Further, an inert gas supplier (which is an inert gas supply structure or an inert gas supply system) is constituted mainly by the gas supply pipes 232e through 232g, the MFCs 241e through 241g and the valves 243e through 243g.

Any one or an entirety of the gas suppliers described above may be embodied as an integrated gas supply system 248 in which the components such as the valves 243a through 243g and the MFCs 241a through 241g are integrated. The integrated gas supply system 248 is connected to the respective gas supply pipes 232a through 232g. An operation of the integrated gas supply system 248 to supply various gases into the gas supply pipes 232a through 232g, for example, operations such as an operation of opening and closing the valves 243a through 243g and an operation of adjusting flow rates of the gases through the MFCs 241a through 241g may be controlled by a controller 121 which will be described later. The integrated gas supply system 248 may be embodied as an integrated structure (integrated unit) of an all-in-one type or a divided type. The integrated gas supply system 248 may be attached to or detached from the components such as the gas supply pipes 232a through 232g on a basis of the integrated structure. Operations such as maintenance, replacement and addition for the integrated gas supply system 248 may be performed on a basis of the integrated structure.

The exhaust port 231a through which an inner atmosphere of the process chamber 201 is exhausted is provided at a lower side wall of the reaction tube 203. As shown in FIG. 2, the exhaust port 231a is arranged at a location so as to face the nozzles 249a through 249c (the gas supply holes 250a through the gas supply holes 250c) with the wafer 200 interposed therebetween when viewed from above. The exhaust port 231a may be provided so as to extend upward from the lower portion toward the upper portion of the reaction tube 203 along a side wall of the reaction tube 203 (that is, along the wafer arrangement region). An exhaust pipe 231 is connected to the exhaust port 231a. For example, the exhaust pipe 231 is made of a metal material such as SUS. A vacuum pump 246 serving as a vacuum exhaust apparatus is connected to the exhaust pipe 231 through a pressure sensor 245 and an APC (Automatic Pressure Controller) valve 244. The pressure sensor 245 serves as a pressure detector (pressure detection structure) to detect an inner pressure of the process chamber 201, and the APC valve 244 serves as a pressure regulator (pressure adjusting structure). With the vacuum pump 246 in operation, the APC valve 244 may be opened or closed to perform a vacuum exhaust operation of the process chamber 201 or stop the vacuum exhaust operation. With the vacuum pump 246 in operation, the inner pressure of the process chamber 201 may be adjusted by adjusting an opening degree of the APC valve 244 based on pressure information detected by the pressure sensor 245. An exhauster (which is an exhaust structure or an exhaust system) is constituted mainly by the exhaust pipe 231, the APC valve 244 and the pressure sensor 245. The exhauster may further include the vacuum pump 246.

A seal cap 219 serving as a furnace opening lid capable of airtightly sealing (or closing) a lower end opening of the manifold 209 is provided under the manifold 209. For example, the seal cap 219 is made of a metal material such as SUS, and is of a disk shape. An O-ring 220b serving as a seal is provided on an upper surface of the seal cap 219 so as to be in contact with the lower end of the manifold 209. A rotator 267 configured to rotate a boat 217 described later is provided under the seal cap 219. A rotating shaft 255 of the rotator 267 is connected to the boat 217 through the seal cap 219. For example, the rotating shaft 255 of the rotator 267 is made of a metal material such as SUS. As the rotator 267 rotates the boat 217, the wafers 200 accommodated in the boat 217 are rotated. The seal cap 219 is elevated or lowered in the vertical direction by a boat elevator 115 serving as an elevating structure provided outside the reaction tube 203. The boat elevator 115 serves as a transfer device (which is a transfer structure or a transfer system) capable of transferring (loading) the wafers 200 into the process chamber 201 and capable of transferring (unloading) the wafers 200 out of the process chamber 201 by elevating and lowering the seal cap 219.

A shutter 219s serving as a furnace opening lid capable of airtightly sealing (or closing) the lower end opening of the manifold 209 is provided under the manifold 209. The shutter 219s is configured to close the lower end opening of the manifold 209 when the seal cap 219 is lowered by the boat elevator 115 and the boat 217 is unloaded out of the process chamber 201. For example, the shutter 219s is made of a metal material such as SUS, and is of a disk shape. An O-ring 220c serving as a seal is provided on an upper surface of the shutter 219s so as to be in contact with the lower end of the manifold 209. An opening and closing operation of the shutter 219s such as an elevation operation and a rotation operation is controlled by a shutter opener/closer (which is a shutter opening/closing structure) 115s.

The boat 217 (which is a substrate support or a substrate retainer) is configured such that the wafers 200 (for example, 25 wafers to 200 wafers) are accommodated (or supported) in the vertical direction in the boat 217 while the wafers 200 are horizontally oriented with their centers aligned with one another with a predetermined interval (gap) therebetween in a multistage manner. For example, the boat 217 is made of a heat resistant material such as quartz and SiC. For example, a plurality of heat insulation plates 218 made of a heat resistant material such as quartz and SiC are supported at a lower portion of the boat 217 in a multistage manner.

A temperature sensor 263 serving as a temperature detector is installed in the reaction tube 203. A state of electric conduction to the heater 207 is adjusted based on temperature information detected by the temperature sensor 263 such that a desired temperature distribution of an inner temperature of the process chamber 201 can be obtained. The temperature sensor 263 is provided along the inner wall of the reaction tube 203.

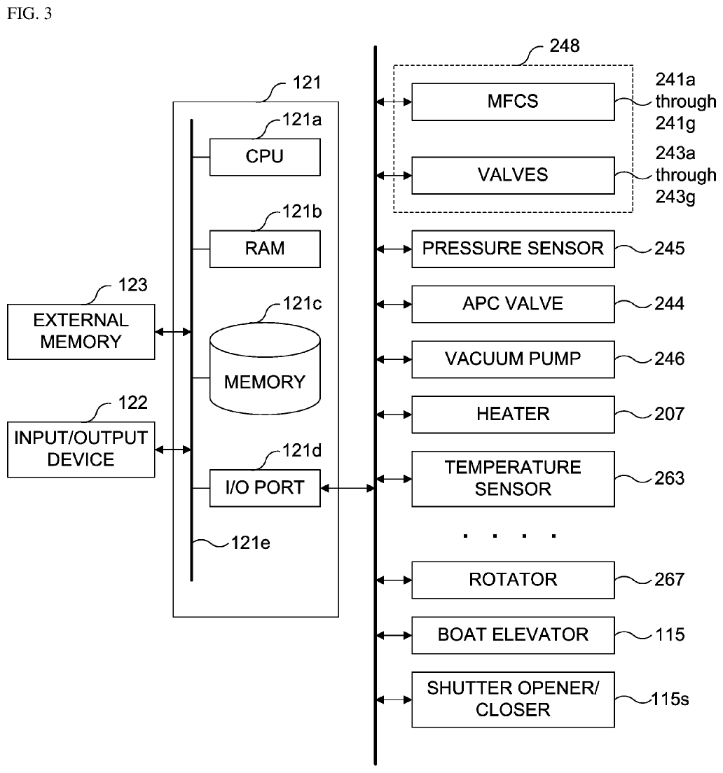

As shown in FIG. 3, the controller 121 serving as a control device (control structure) is constituted by a computer including a CPU (Central Processing Unit) 121a, a RAM (Random Access Memory) 121b, a memory 121c and an I/O port 121d. The RAM 121b, the memory 121c and the I/O port 121d may exchange data with the CPU 121a through an internal bus 121e. For example, an input/output device 122 constituted by a component such as a touch panel is connected to the controller 121. Further, the controller 121 is configured such that an external memory 123 can be connected to the controller 121.

The memory 121c is configured by a component such as a flash memory, a hard disk drive (HDD) and a solid state drive (SSD). For example, a control program configured to control an operation of the substrate processing apparatus and a process recipe containing information on sequences and conditions of a substrate processing described later may be readably stored in the memory 121c. The process recipe is obtained by combining steps (sequences or processes) of the substrate processing described later such that the controller 121 can execute the steps to acquire a predetermined result, and functions as a program. Hereinafter, the process recipe and the control program may be collectively or individually referred to as a “program”. In addition, the process recipe may also be simply referred to as a “recipe”. Thus, in the present specification, the term “program” may refer to the recipe alone, may refer to the control program alone or may refer to both of the recipe and the control program. The RAM 121b functions as a memory area (work area) where a program or data read by the CPU 121a is temporarily stored.

The I/O port 121d is connected to the components described above such as the MFCs 241a through 241g, the valves 243a through 243g, the pressure sensor 245, the APC valve 244, the vacuum pump 246, the temperature sensor 263, the heater 207, the rotator 267, the boat elevator 115 and the shutter opener/closer 115s.

The CPU 121a is configured to read the control program from the memory 121c and execute the read control program. In addition, the CPU 121a is configured to read the recipe from the memory 121c, for example, in accordance with an operation command inputted from the input/output device 122. In accordance with the contents of the read recipe, the CPU 121a may be configured to be capable of controlling various operations such as flow rate adjusting operations for various gases by the MFCs 241a through 241g, opening and closing operations of the valves 243a through 243g, an opening and closing operation of the APC valve 244, a pressure regulating operation (pressure adjusting operation) by the APC valve 244 based on the pressure sensor 245, a start and stop operation of the vacuum pump 246, a temperature adjusting operation by the heater 207 based on the temperature sensor 263, an operation of adjusting a rotation and a rotation speed of the boat 217 by the rotator 267, an elevating and lowering operation of the boat 217 by the boat elevator 115 and an opening and closing operation of the shutter 219s by the shutter opener/closer 115s.

The controller 121 may be embodied by installing the above-described program stored in the external memory 123 into the computer. For example, the external memory 123 may include a magnetic disk such as a hard disk drive (HDD), an optical disk such as a CD, a magneto-optical disk such as an MO and a semiconductor memory such as a USB memory and a solid state drive (SSD). The memory 121c or the external memory 123 may be embodied by a non-transitory computer readable recording medium. Hereafter, the memory 121c and the external memory 123 may be collectively or individually referred to as a “recording medium”. Thus, in the present specification, the term “recording medium” may refer to the memory 121c alone, may refer to the external memory 123 alone or may refer to both of the memory 121c and the external memory 123. Instead of the external memory 123, a communication interface such as the Internet and a dedicated line may be used for providing the program to the computer.

(2) Substrate Processing

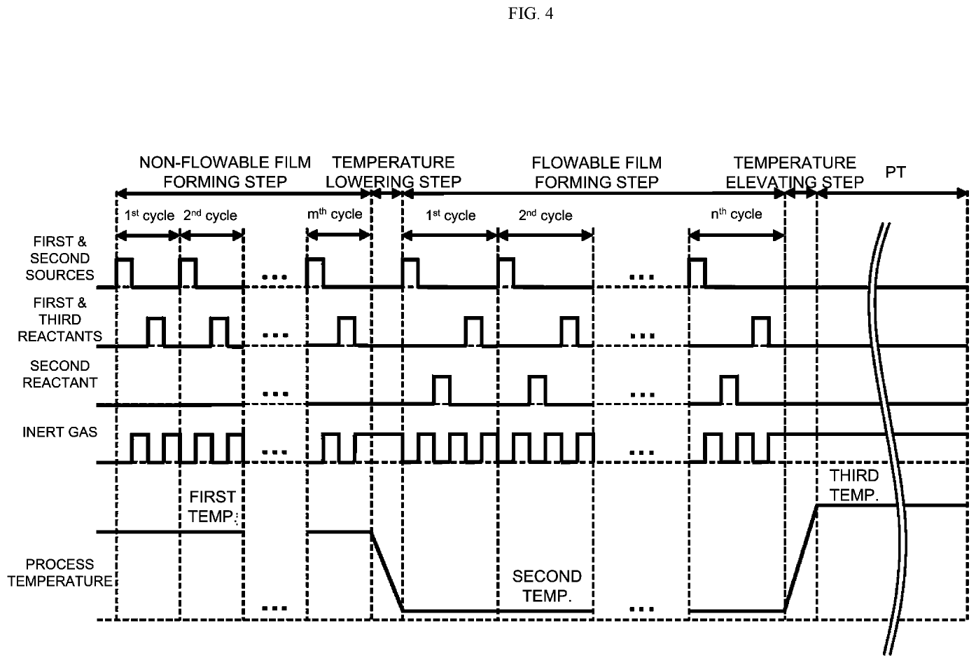

Hereinafter, an exemplary flow (exemplary process sequence) of the substrate processing such as a film-forming process of forming a film on the wafer 200 serving as the substrate will be described mainly with reference to FIG. 4. The substrate processing serves as a part of a manufacturing process of a semiconductor device, and is performed by using the substrate processing apparatus described above. The present embodiment will be described by way of an example in which a silicon substrate (silicon wafer) is used as the wafer 200. A concave portion (hereinafter, also referred to as a “recess”) such as a trench and a hole is provided on a surface of the silicon substrate (that is, the wafer 200), and an oxygen-containing film such as a film containing silicon (Si) and oxygen (O) (hereinafter, also referred to as a “Si- and O-containing film”) is exposed on the surface of the silicon substrate (that is, the wafer 200). Further, the oxygen-containing film exposed on the surface of the wafer 200 may be a natural oxide film. In the following descriptions, the operations of components constituting the substrate processing apparatus are controlled by the controller 121.

As shown in FIG. 4, the exemplary process sequence of the substrate processing according to the present embodiment may include: a step A (that is, a non-flowable film forming step) of forming a film without fluidity (hereinafter, also referred to as a “non-flowable film”) on the surface of the wafer 200 on which a recess is provided and the oxygen-containing film is exposed by supplying the first material (for example, the first source and the first reactant) to the wafer 200 at a first temperature; and a step B (that is, a flowable film forming step) of forming a film with the fluidity (hereinafter, also referred to as a “flowable film”) on the non-flowable film by supplying the second material (for example, the second source, the second reactant and the third reactant) to the wafer 200 at a second temperature lower than the first temperature.

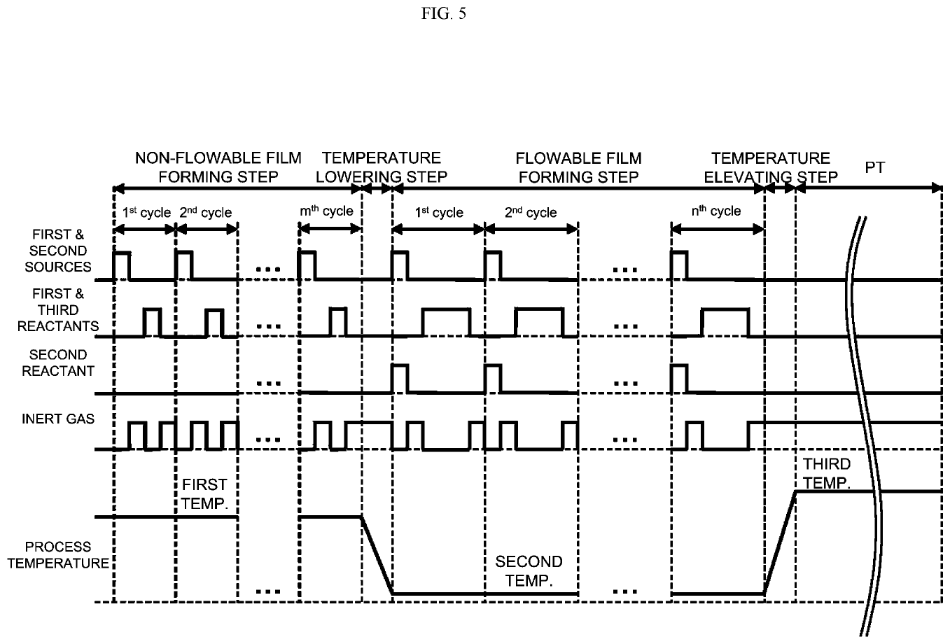

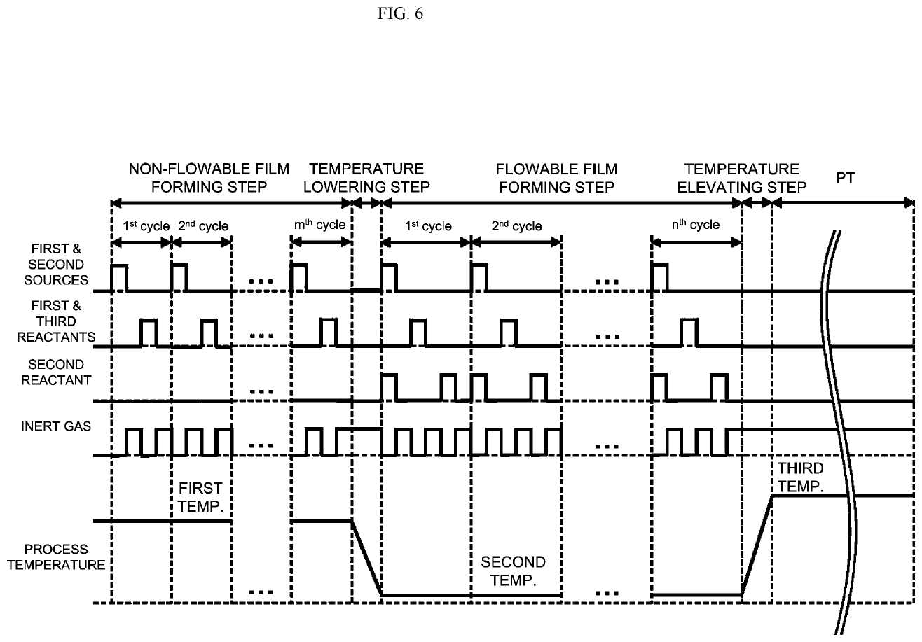

FIG. 4 shows an example in which the first source and the second source are the same source and the first reactant and the third reactant are the same reactant. That is, FIG. 4 shows the example in which a molecular structure of the first source is the same as that of the second source and a molecular structure of the first reactant is the same as that of the third reactant. The same also applies to examples of a second embodiment and a third embodiment shown in FIGS. 5 and 6.

Further, the exemplary process sequence of the substrate processing according to the present embodiment may further include: a step C (that is, a post-treatment) of modifying the flowable film by performing a post-treatment to the wafer 200 after the flowable film is formed on the non-flowable film at a third temperature higher than the second temperature. In the present specification, the post-treatment may also be referred to as a “PT”.

Further, in the step A of the exemplary process sequence of the substrate processing according to the present embodiment, a first cycle including a step A1 of supplying the first source to the wafer 200 and a step A2 of supplying the first reactant to the wafer 200 may be performed a first predetermined number of times (m times, m is an integer equal to or greater than 1). In the first cycle of the exemplary process sequence of the substrate processing according to the present embodiment, the steps A1 and A2 are performed non-simultaneously.

Further, in the step B of the exemplary process sequence of the substrate processing according to the present embodiment, a second cycle including a step B1 of supplying the second source to the wafer 200, a step B2 of supplying the second reactant to the wafer 200 and a step B3 of supplying the third reactant to the wafer 200 may be performed a second predetermined number of times (n times, n is an integer equal to or greater than 1). In the second cycle of the exemplary process sequence of the substrate processing according to the present embodiment, the steps B1, B2 and B3 are performed non-simultaneously.

In the present specification, the exemplary process sequence described above may be illustrated as follows for simplicity. Process sequences of embodiments such as the second embodiment and the third embodiment and modified examples, which will be described later, will be also represented in the same manner.

(first source→first reactant)×m→(second source→second reactant→third reactant)×n→PT

In the present specification, the term “wafer” may refer to “a wafer itself”, or may refer to “a wafer and a stacked structure (aggregated structure) of a predetermined layer (or layers) or a film (or films) formed on a surface of the wafer”. In the present specification, the term “a surface of a wafer” may refer to “a surface of a wafer itself”, or may refer to “a surface of a predetermined layer (or a predetermined film) formed on a wafer”. Thus, in the present specification, “forming a predetermined layer (or a film) on a wafer” may refer to “forming a predetermined layer (or a film) directly on a surface of a wafer itself”, or may refer to “forming a predetermined layer (or a film) on a surface of another layer (or another film) formed on a wafer”. In the present specification, the terms “substrate” and “wafer” may be used as substantially the same meaning.

<Wafer Charging Step and Boat Loading Step>

The wafers 200 are charged (transferred) into the boat 217 (wafer charging step). Then, the shutter 219s is moved by the shutter opener/closer 115s to open the lower end opening of the manifold 209 (shutter opening step). Thereafter, as shown in FIG. 1, the boat 217 supporting the wafers 200 is elevated by the boat elevator 115 and loaded (transferred) into the process chamber 201 (boat loading step). With the boat 217 loaded, the seal cap 219 airtightly seals the lower end of the manifold 209 via the O-ring 220b.

<Pressure Adjusting Step and Temperature Adjusting Step>

After the boat loading step is completed, the vacuum pump 246 vacuum-exhausts (decompresses and exhausts) the inner atmosphere of the process chamber 201 (that is, a space in which the wafers 200 are accommodated) such that the inner pressure of the process chamber 201 reaches and is maintained at a desired pressure (vacuum degree). When the vacuum pump 246 vacuum-exhausts the inner atmosphere of the process chamber 201, the inner pressure of the process chamber 201 is measured by the pressure sensor 245, and the APC valve 244 is feedback-controlled based on the pressure information detected by the pressure sensor 245 (pressure adjusting step). In addition, the heater 207 heats the process chamber 201 such that a temperature of the wafer 200 in the process chamber 201 reaches and is maintained at a desired process temperature. When the heater 207 heats the process chamber 201, the state of the electric conduction to the heater 207 is feedback-controlled based on the temperature information detected by the temperature sensor 263 such that a desired temperature distribution of the inner temperature of the process chamber 201 can be obtained (temperature adjusting step). In addition, a rotation of the wafer 200 is started by the rotator 267. The vacuum pump 246 continuously vacuum-exhausts the inner atmosphere of the process chamber 201, the heater 207 continuously heats the wafer 200 in the process chamber 201 and the rotator 267 continuously rotates the wafer 200 until at least a processing of the wafer 200 is completed.

<Film Forming Process>

Thereafter, the step A, the step B and the step C are sequentially performed in this order so as to perform the film-forming process of forming the film on the wafer 200. In the present specification, the film-forming process of forming the film inside the recess (concave structure) provided on the surface of the wafer 200 may also be referred to as a “embedding process” or “filling process”. Hereinafter, the steps mentioned above will be described in detail.

<Step A (Non-flowable Film Forming Step)>

In the step A, by supplying the first material (for example, the first source and the first reactant) to the wafer 200 on which a recess is provided where the oxygen-containing film is exposed in the process chamber 201, the non-flowable film is formed on the surface of the wafer 200. In the step A, the first source and the first reactant are supplied under a condition where a chemical adsorption or a thermal decomposition of the first source occurs more dominantly than a physical adsorption of the first source in a case where the first source is provided alone.

Specifically, in the step A, the first cycle including the step A1 of supplying the first source to the wafer 200 and the step A2 of supplying the first reactant to the wafer 200 is performed the first predetermined number of times (m times, m is an integer equal to or greater than 1). Hereinafter, the step A including the step A1 and the step A2 will be described in more detail.

<Step A1>

In the step A1, the first source is supplied to the wafer 200 in the process chamber 201.

Specifically, the valve 243a is opened such that the first source is supplied into the gas supply pipe 232a. A flow rate of the first source supplied into the gas supply pipe 232a is adjusted by the MFC 241a. Then, the first source whose flow rate is adjusted is supplied into the process chamber 201 through the nozzle 249a, and is exhausted through the exhaust port 231a. Thereby, the first source is supplied to the wafer 200. Thus, the step A1 may also be referred to as a “first source supply step”. In the present step, simultaneously with a supply of the first source, the valves 243e through 243g may be opened such that the inert gas is supplied into the process chamber 201 through each of the nozzles 249a, 249b and 249c.

After a predetermined period of time has elapsed, the valve 243a is closed to stop the supply of the first source into the process chamber 201. Then, the inner atmosphere of the process chamber 201 is vacuum-exhausted such that a gas phase substance remaining in the process chamber 201 can be removed from the process chamber 201. When the inner atmosphere of the process chamber 201 is vacuum-exhausted, the valves 243e through 243g are opened such that the inert gas is supplied into the process chamber 201 through each of the nozzles 249a, 249b and 249c. The inert gas supplied through the nozzles 249a, 249b and 249c acts as the purge gas, and thereby, the space in which the wafers 200 are accommodated (that is, the inner atmosphere of the process chamber 201) is purged (purge step).

As the first source, for example, a silane-based gas containing silicon (Si) as a primary element (main element) constituting the non-flowable film formed on the surface of the wafer 200 may be used. As the silane-based gas, for example, a gas containing silicon and a halogen (that is, a halosilane-based gas) may be used. As the halogen, for example, an element such as chlorine (Cl), fluorine (F), bromine (Br) and iodine (I) may be used. That is, as the halosilane-based gas, for example, a gas such as a chlorosilane-based gas, a fluorosilane-based gas, a bromosilane-based gas and an iodosilane-based gas may be used. As the halosilane-based gas, for example, a gas containing silicon, carbon (C) and the halogen (that is, an organic halosilane-based gas) may be used. As the organic halosilane-based gas, for example, a gas containing silicon, carbon and chlorine (Cl) (that is, an organic chlorosilane-based gas) may be used.

As the first source, for example, a silane-based gas free of carbon and halogen such as monosilane (SiH₄, abbreviated as MS) gas and disilane (Si₂H₆, abbreviated as DS) gas, a halosilane-based gas free of carbon such as dichlorosilane (SiH₂Cl₂, abbreviated as DCS) gas and hexachlorodisilane (Si₂Cl₆, abbreviated as HCDS) gas, an alkylsilane-based gas such as trimethylsilane (SiH(CH₃)₃, abbreviated as TMS) gas, dimethylsilane (SiH₂(CH₃)₂, abbreviated as DMS) gas, triethylsilane (SiH(C₂Hs)₃, abbreviated as TES) gas and diethylsilane (SiH₂(C₂Hs)₂, abbreviated as DES) gas, an alkylenehalosilane-based gas such as bis (trichlorosilyl) methane ((SiCl₃)₂CH₂, abbreviated as BTCSM) gas and 1, 2-bis (trichlorosilyl) ethane ((SiCl₃)₂C₂H₄, abbreviated as BTCSE) gas, or an alkylhalosilane-based gas such as trimethylchlorosilane (SiCl(CH₃)₃, abbreviated as TMCS) gas, dimethyldichlorosilane (SiCl₂(CH₃)₂, abbreviated as DMDCS) gas, triethylchlorosilane (SiCl(C₂H₅)₃, abbreviated as TECS) gas, diethyldichlorosilane (SiCl₂(C₂H₅)₂, abbreviated as DEDCS) gas, 1, 1, 2,2-tetrachloro-1, 2-dimethyldisilane ((CH₃)₂Si₂Cl₄, abbreviated as TCDMDS) gas and 1, 2-dichloro-1, 1, 2, 2-tetramethyldisilane ((CH₃)₄Si₂Cl₂, abbreviated as DCTMDS) gas may be used. Further, as the first source, for example, an alkylaminosilane-based gas such as (dimethylamino) trimethylsilane ((CH₃)₂NSi(CH₃)₃, abbreviated as DMATMS) gas, (diethylamino) triethylsilane ((C₂H₅)₂NSi(C₂H₅)₃, abbreviated as DEATES) gas, (dimethylamino) triethylsilane ((CH₃)₂NSi(C₂H₅)₃, abbreviated as DMATES) gas, (diethylamino) trimethylsilane ((C₂Hs)₂NSi(CH₃)₃, abbreviated as DEATMS) gas, (trimethylsilyl) amine ((CH₃)₃SiNH₂, abbreviated as TMSA) gas, (triethylsilyl) amine ((C₂H₅)₃SiNH₂, abbreviated as TESA), (dimethylamino) silane ((CH₃)₂NSiH₃, abbreviated as DMAS) gas and (diethylamino) silane ((C₂Hs)₂NSiH₃, abbreviated as DEAS) gas may be used. As the first source, for example, one or more of the gases (that is, silicon-containing sources) exemplified above may be used.

As described above, some of the first source may contain the halogen and is free of an amino group. For example, some of the first source may contain a chemical bond between silicon and silicon (Si—Si bond). For example, some of the first source may contain silicon and the halogen, or may contain silicon, the halogen and carbon. For example, some of the first source may contain the alkyl group and the halogen.

As the inert gas, for example, nitrogen (N₂) gas or a rare gas such as argon (Ar) gas, helium (He) gas, neon (Ne) gas and xenon (Xe) gas may be used. The same also applies to the steps described below. As the inert gas, for example, one or more of the gases exemplified above as the inert gas may be used.

<Step A2>

In the step A2, the first reactant is supplied to the wafer 200 in the process chamber 201.

Specifically, the valve 243b is opened such that the first reactant is supplied into the gas supply pipe 232b. A flow rate of the first reactant supplied into the gas supply pipe 232b is adjusted by the MFC 241b. Then, the first reactant whose flow rate is adjusted is supplied into the process chamber 201 through the nozzle 249b, and is exhausted through the exhaust port 231a. Thereby, the first reactant is supplied to the wafer 200. Thus, the step A2 may also be referred to as a “first reactant supply step”. In the present step, simultaneously with a supply of the first reactant, the valves 243e through 243g may be opened such that the inert gas is supplied into the process chamber 201 through each of the nozzles 249a, 249b and 249c.

After a predetermined period of time has elapsed, the valve 243b is closed to stop the supply of the first reactant into the process chamber 201. Then, by substantially the same process procedure as the purge step in the step A1, the inner atmosphere of the process chamber 201 is vacuum-exhausted such that a gas phase substance remaining in the process chamber 201 can be removed from the process chamber 201.

As the first reactant, for example, a gas containing nitrogen (N) and hydrogen (H) may be used. Hereinafter, the gas containing nitrogen and hydrogen may also be referred to as an “N- and H-containing gas”. As the N- and H-containing gas, for example, a hydrogen nitride-based gas such as ammonia (NH₃) gas, an ethylamine-based gas such as monoethylamine (C₂H₅NH₂, abbreviated as MEA) gas, diethylamine ((C₂H₅)₂NH, abbreviated as DEA) gas and triethylamine ((C₂H₅)₃N, abbreviated as TEA) gas, a methylamine-based gas such as monomethylamine (CH₃NH₂, abbreviated as MMA) gas, dimethylamine ((CH₃)₂NH, abbreviated as DMA) gas and trimethylamine ((CH₃)₃N, abbreviated as TMA) gas, a cyclic amine-based gas such as pyridine (C₅H₅N) gas and piperazine (C₄H₁₀N₂) gas, or an organic hydrazine-based gas such as monomethylhydrazine ((CH₃)HN₂H₂, abbreviated as MMH) gas, dimethylhydrazine ((CH₃)₂N₂H₂, abbreviated as DMH) gas, trimethylhydrazine ((CH₃)₂N₂(CH₃)H, abbreviated as TMH) gas may be used. Since each of the amine-based gas and the organic hydrazine-based gas contains carbon (C), nitrogen (N) and hydrogen (H), each of the amine-based gas and the organic hydrazine-based gas may also be referred to as a gas containing carbon, nitrogen and hydrogen. Hereinafter, the gas containing carbon, nitrogen and hydrogen may also be referred to as a “C-, N- and H-containing gas”. The amine-based gas containing the alkyl group may also be referred to as an “alkylamine-based gas”. Instead of the C-, N- and H-containing gas, a carbon (C)-containing gas (that is, a gas containing carbon and hydrogen) such as ethylene (C₂H₄) gas, acetylene (C₂H₂) gas, propylene (C₃H₆) gas and a nitrogen (N)-containing gas (that is, a gas containing nitrogen and hydrogen) such as the NH₃ gas may be supplied simultaneously or non-simultaneously. As the first reactant, one or more of the gases exemplified above as the N- and H-containing gas (N- and H-containing reactant) and the C-, N- and H-containing gas (C-, N- and H-containing reactant) may be used.

<Performing First Cycle First Predetermined Number of Times>

The first cycle in which the step A1 and the step A2 described above are performed non-simultaneously (that is, in a non-synchronized manner) in this order is performed the first predetermined number of times (m times, wherein m is an integer equal to or greater than 1). According to the present embodiment, for example, the first cycle is performed the first predetermined number of times under the condition where the chemical adsorption or the thermal decomposition of the first source occurs more dominantly than the physical adsorption of the first source in a case where the first source is provided alone. Further, in FIG. 4, “1^{st} cycle”, “2^{nd} cycle” and “m^{th} cycle” related to the step A indicate “a first execution of the first cycle”, “a second execution of the first cycle” and “an m^{th} execution of the first cycle”, respectively.

For example, process conditions when the first source is supplied in the step A1 are as follows:
A process temperature (first temperature): from 350° C. to 700° C., preferably from 450° C. to 650° C.;
A process pressure: from 1 Pa to 2,666 Pa, preferably from 67 Pa to 1,333 Pa;
A supply flow rate of the first source: from 0.001 slm to 2 slm, preferably from 0.01 slm to 1 slm;
A supply time (time duration) of the first source: from 1 second to 120 seconds, preferably from 1 second to 60 seconds; and
A supply flow rate of the inert gas (for each gas supply pipe): from 0 slm to 20 slm, preferably from 0.01 slm to 10 slm.

In the present specification, a notation of a numerical range such as “from 350° C. to 700° C.” means that a lower limit and an upper limit are included in the numerical range. Therefore, for example, a numerical range “from 350° C. to 700° C.” means a range equal to or higher than 350° C. and equal to or less than 700° C. The same also applies to other numerical ranges described in the present specification. Further, in the present specification, the process temperature refers to the temperature of the wafer 200 or the inner temperature of the process chamber 201, and the process pressure refers to the inner pressure of the process chamber 201. Further, when a supply flow rate of a gas is zero (0) slm, it refers to a case where the gas is not supplied. The same also applies to the following descriptions.

For example, the process conditions when the first reactant is supplied in the step A2 are as follows:
The process pressure: from 1 Pa to 4,000 Pa, preferably from 1 Pa to 3,000 Pa;
A supply flow rate of the first reactant: from 0.001 slm to 20 slm, preferably from 1 slm to 10 slm; and
A supply time (time duration) of the first reactant: from 1 second to 120 seconds, preferably from 1 second to 60 seconds.

The other process conditions when the first reactant is supplied in the step A2 may be set to be substantially the same as those when the first source is supplied in the step A1.

By supplying the first source in the step A1 in accordance with the process conditions described above, in the step A1, part of the molecular structure of a molecule of the first source can be adsorbed onto the surface of the wafer 200 and a surface inside the recess, that is, a surface of the oxygen-containing film. Further, by supplying the first reactant in the step A2 in accordance with the process conditions described above, in the step A2, the part of the molecular structure of the molecule of the first source adsorbed on the surface of the oxygen-containing film reacts with the first reactant to form a non-flowable layer. The non-flowable layer whose step coverage is high is formed conformally on the surface of the wafer 200 and the surface inside the recess. Further, by performing the first cycle the first predetermined number of times in accordance with the process conditions described above, it is possible to form the non-flowable film of a predetermined thickness on the surface of the wafer 200 and the surface inside the recess, that is, the surface of the oxygen-containing film.

It is preferable that the first cycle described above is performed a plurality of times. That is, it is preferable that the first cycle is repeatedly performed the plurality of times until the non-flowable film of a desired thickness is obtained by controlling the non-flowable layer formed in each execution of the first cycle to be thinner than the non-flowable film of the desired thickness and by stacking the non-flowable layer by repeatedly performing the first cycle. Further, it is preferable that a thickness of the non-flowable film is equal to or less than a thickness of the flowable film described later (preferably, the non-flowable film is thinner than the flowable film). For example, it is preferable that the thickness of the non-flowable film is set to be 0.2 nm or more and 10 nm or less.

When using various substances exemplified above as the first source or the first reactant, for example, it is possible to form the non-flowable film such as a silicon nitride film (SiN film) serving as a film containing silicon and nitrogen (hereinafter, also referred to as a “Si- and N-containing film”) and a silicon carbonitride film (SiCN film) serving as a film containing silicon, carbon and nitrogen (hereinafter, also referred to as a “Si-, C- and N-containing film”). Since the various substances exemplified above as the first source or the first reactant do not contain oxygen (O), the non-flowable film is an oxygen-free film. Further, a hydrophilicity of the non-flowable film is lower than that of the oxygen-containing film serving as a base (underlying film) of a film formation. For example, when the oxygen-containing film serving as the base of the film formation is a hydrophilic film, it is preferable that the non-flowable film is a non-hydrophilic film (that is, a hydrophobic film).

<Step B (Flowable Film Forming Step)>

After the non-flowable film is formed on the surface of the wafer 200, an output of the heater 207 is adjusted so as to change the temperature of the wafer 200 to the second temperature lower than the first temperature described above (temperature lowering step). Then, the step B is performed when the temperature of the wafer 200 reaches and is stably maintained at the second temperature.

In the step B, by supplying the second material (for example, the second source, the second reactant and the third reactant) to the wafer 200 in the process chamber 201, the flowable film is formed on the non-flowable film formed by performing the step A. In the step B, the second source, the second reactant and the third reactant are supplied under a condition where a physical adsorption of the second source occurs more dominantly than a chemical adsorption of the second source without thermally decomposing the second source in a case where the second source is provided alone.

Specifically, in the step B, the second cycle including the step B1 of supplying the second source to the wafer 200, the step B2 of supplying the second reactant to the wafer 200 and the step B3 of supplying the third reactant to the wafer 200 is performed the second predetermined number of times (n times, n is an integer equal to or greater than 1). Hereinafter, the step B including the step B1, the step B2 and the step B3 will be described in more detail.

<Step B1>

In the step B1, the second source is supplied to the wafer 200 in the process chamber 201.

Specifically, the valve 243a is opened such that the second source is supplied into the gas supply pipe 232a. A flow rate of the second source supplied into the gas supply pipe 232a is adjusted by the MFC 241a. Then, the second source whose flow rate is adjusted is supplied into the process chamber 201 through the nozzle 249a, and is exhausted through the exhaust port 231a. Thereby, the second source is supplied to the wafer 200. Thus, the step B1 may also be referred to as a “second source supply step”. In the present step, simultaneously with a supply of the second source, the valves 243e through 243g may be opened such that the inert gas is supplied into the process chamber 201 through each of the nozzles 249a, 249b and 249c.

After a predetermined period of time has elapsed, the valve 243a is closed to stop the supply of the second source into the process chamber 201. Then, by substantially the same process procedure as the purge step in the step A1, the inner atmosphere of the process chamber 201 is vacuum-exhausted such that a gas phase substance remaining in the process chamber 201 can be removed from the process chamber 201.

As the second source, for example, a silane-based gas containing silicon (Si) as a primary element (main element) constituting the flowable film formed on the surface of the wafer 200 may be used. As the silane-based gas, for example, a gas containing silicon and a halogen (that is, a halosilane-based gas) may be used. As the halogen, for example, an element such as chlorine (Cl), fluorine (F), bromine (Br) and iodine (I) may be used. That is, as the halosilane-based gas, for example, a gas such as a chlorosilane-based gas, a fluorosilane-based gas, a bromosilane-based gas and an iodosilane-based gas may be used. As the halosilane-based gas, for example, a gas containing silicon, carbon (C) and the halogen (that is, an organic halosilane-based gas) may be used. As the organic halosilane-based gas, for example, a gas containing silicon, carbon and chlorine (that is, an organic chlorosilane-based gas) may be used.

As the second source, for example, a silane-based gas free of carbon and halogen such as the MS gas and the DS gas, a halosilane-based gas free of carbon such as the DCS gas and the HCDS gas, an alkylsilane-based gas such as the TMS gas, the DMS gas, the TES gas and the DES gas, an alkylenehalosilane-based gas such as the BTCSM gas and the BTCSE gas, or an alkylhalosilane-based gas such as the TMCS gas, the DMDCS gas, the TECS gas, the DEDCS gas, the TCDMDS gas and the DCTMDS gas may be used. Further, as the second source, one or more of the gases (that is, sources containing silicon) exemplified above may be used. As the second source, a source whose molecular structure is the same as that of the first source may be used.

As described above, some of the second source may contain the halogen and is free of the amino group. For example, some of the second source may contain the chemical bond between silicon and silicon (Si—Si bond). For example, some of the second source may contain silicon and the halogen, or may contain silicon, the halogen and carbon. For example, some of the second source may contain the alkyl group and the halogen.

<Step B2>

In the step B2, the second reactant is supplied to the wafer 200 in the process chamber 201.

Specifically, the valve 243c is opened such that the second reactant is supplied into the gas supply pipe 232c. A flow rate of the second reactant supplied into the gas supply pipe 232c is adjusted by the MFC 241c. Then, the second reactant whose flow rate is adjusted is supplied into the process chamber 201 through the nozzle 249c, and is exhausted through the exhaust port 231a. Thereby, the second reactant is supplied to the wafer 200. Thus, the step B2 may also be referred to as a “second reactant supply step”. In the present step, simultaneously with a supply of the second reactant, the valves 243e through 243g may be opened such that the inert gas is supplied into the process chamber 201 through each of the nozzles 249a, 249b and 249c.

After a predetermined period of time has elapsed, the valve 243c is closed to stop the supply of the second reactant into the process chamber 201. Then, by substantially the same process procedure as the purge step in the step A1, the inner atmosphere of the process chamber 201 is vacuum-exhausted such that a gas phase substance remaining in the process chamber 201 can be removed from the process chamber 201.

As the second reactant, for example, a gas containing nitrogen (N) and hydrogen (H) (“N- and H-containing gas) may be used. As the N- and H-containing gas, for example, a hydrogen nitride-based gas such as the NH₃ gas, an ethylamine-based gas such as the MEA gas, the DEA gas and the TEA gas, a methylamine-based gas such as the MMA gas, the DMA gas and the TMA gas, a cyclic amine-based gas such as C₅H₅N gas and C₄H₁₀N₂ gas, or an organic hydrazine-based gas such as the MMH gas, the DMH gas and the TMH gas may be used. As described above, each of the amine-based gas and the organic hydrazine-based gas may also be referred to as a gas containing carbon, nitrogen and hydrogen (“C-, N- and H-containing gas”). The amine-based gas containing the alkyl group may also be referred to as the “alkylamine-based gas”. Instead of the C-, N- and H-containing gas, a carbon (C)-containing gas (that is, a gas containing carbon and hydrogen) such as the C₂H₄ gas, the C₂H₂ gas, the C₃H₆ gas and a nitrogen (N)-containing gas (that is, a gas containing nitrogen and hydrogen) such as the NH₃ gas may be supplied simultaneously or non-simultaneously. As the second reactant, one or more of the gases exemplified above as the N- and H-containing gas (N- and H-containing reactant) and the C-, N- and H-containing gas (C-, N- and H-containing reactant) may be used. As the second reactant, a reactant whose molecular structure is the same as that of the first reactant may be used.

<Step B3>

In the step B, the third reactant is supplied to the wafer 200 in the process chamber 201.

Specifically, the valve 243d is opened such that the third reactant is supplied into the gas supply pipe 232d. A flow rate of the third reactant supplied into the gas supply pipe 232d is adjusted by the MFC 241d. Then, the third reactant whose flow rate is adjusted is supplied into the process chamber 201 through the gas supply pipe 232b and the nozzle 249b, and is exhausted through the exhaust port 231a. Thereby, the third reactant is supplied to the wafer 200. Thus, the step B3 may also be referred to as a “third reactant supply step”. In the present step, simultaneously with a supply of the third reactant, the valves 243e through 243g may be opened such that the inert gas is supplied into the process chamber 201 through each of the nozzles 249a, 249b and 249c.

After a predetermined period of time has elapsed, the valve 243d is closed to stop the supply of the third reactant into the process chamber 201. Then, by substantially the same process procedure as the purge step in the step A1, the inner atmosphere of the process chamber 201 is vacuum-exhausted such that a gas phase substance remaining in the process chamber 201 can be removed from the process chamber 201.

As the third reactant, for example, a gas containing nitrogen (N) and hydrogen (H) (“N- and H-containing gas) may be used. As the N- and H-containing gas, for example, a hydrogen nitride-based gas such as the NH₃ gas, an ethylamine-based gas such as the MEA gas, the DEA gas and the TEA gas, a methylamine-based gas such as the MMA gas, the DMA gas and the TMA gas, a cyclic amine-based gas such C₅H₅N gas and C₄H₁₀N₂ gas, or an organic hydrazine-based gas such as the MMH gas, the DMH gas and the TMH gas may be used. As described above, each of the amine-based gas and the organic hydrazine-based gas may also be referred to as a gas containing carbon, nitrogen and hydrogen (“C-, N- and H-containing gas”). The amine-based gas containing the alkyl group may also be referred to as the “alkylamine-based gas”. Instead of the C-, N- and H-containing gas, a carbon (C)-containing gas (that is, a gas containing carbon and hydrogen) such as the C₂H₄ gas, the C₂H₂ gas, the C₃H₆ gas and a nitrogen (N)-containing gas (that is, a gas containing nitrogen and hydrogen) such as the NH₃ gas may be supplied simultaneously or non-simultaneously. As the third reactant, one or more of the gases exemplified above as the N- and H-containing gas (N- and H-containing reactant) and the C-, N- and H-containing gas (C-, N- and H-containing reactant) may be used. As the third reactant, a reactant whose molecular structure is the same as that of the first reactant may be used.

<Performing Second Cycle Second Predetermined Number of Times>

The second cycle in which the step B1, the step B2 and the step B3 described above are performed non-simultaneously (that is, in a non-synchronized manner) in this order is performed the second predetermined number of times (n times, wherein n is an integer equal to or greater than 1). According to the present embodiment, for example, the second cycle is performed the second predetermined number of times under the condition where the physical adsorption of the second source occurs more dominantly than the chemical adsorption of the second source without thermally decomposing the second source in a case where the second source is provided alone. Further, in FIG. 4, “1^{st} cycle”, “2^{nd} cycle” and “n^{th} cycle” related to the step B indicate “a first execution of the second cycle”, “a second execution of the second cycle” and “an n^{th} execution of the second cycle”, respectively.

For example, the process conditions when the second source is supplied in the step B1 are as follows:
The process temperature (second temperature): from 0° C. to 150° C., preferably from 10° C. to 100° C., and more preferably from 20° C. to 60° C.;
The process pressure: from 10 Pa to 6,000 Pa, preferably from 50 Pa to 2,000 Pa;
A supply flow rate of the second source: from 0.01 slm to 1 slm;
A supply time (time duration) of the second source: from 1 second to 300 seconds; and
The supply flow rate of the inert gas (for each gas supply pipe): from 0 slm to 20 slm, preferably from 0.01 slm to 10 slm.

For example, the process conditions when the second reactant is supplied in the step B2 are as follows:
A supply flow rate of the second reactant: from 0.01 slm to 5 slm; and
A supply time (time duration) of the second reactant: from 1 second to 300 seconds.

The other process conditions when the second reactant is supplied in the step B2 may be set to be substantially the same as those when the second source is supplied in the step B1.

For example, the process conditions when the third reactant is supplied in the step B3 are as follows:
A supply flow rate of the third reactant: from 0.01 slm to 5 slm; and
A supply time (time duration) of the third reactant: from 1 second to 300 seconds.

The other process conditions when the third reactant is supplied in the step B3 may be set to be substantially the same as those when the second source is supplied in the step B1.

By performing the second cycle the second predetermined number of times in accordance with the process conditions described above, an oligomer containing the element or elements contained in at least one selected from the group of the second source, the second reactant and the third reactant can be generated, grown, and flowed. As a result, it is possible to form an oligomer-containing film serving as the flowable film on the non-flowable film formed on the surface of the wafer 200 and inside the recess. Thereby, it is possible to fill an inside of the recess with the flowable film. In the present specification, the “oligomer” refers to a polymer with a relatively low molecular weight (for example, molecular weight of 10,000 or less) to which a relatively small amount of monomers (for example, 10 to 100 monomers) are bonded. When using the second source, the second reactant and the third reactant as exemplified above, for example, the non-flowable film may contain various elements such as silicon, chlorine and nitrogen and a substance represented by a chemical formula CₓH₂ₓ₊₁ (x is an integer from 1 to 3) such as CH₃ and C₂H.

By performing the second cycle including the step B1, the step B2 and the step B3 in accordance with the process conditions described above, it is possible to remove and discharge (exhaust) a surplus substance (which is contained in a surface layer of the oligomer or inside the oligomer) such as a surplus gas, impurities containing chlorine (Cl) and reaction by-products (hereinafter, also simply referred to as “by-products”) while promoting a growth and a flow of the oligomer formed on the surface of the wafer 200 and inside the recess.

When the process temperature described above is set to be lower than 0° C., the second source supplied into the process chamber 201 may be easily liquefied. Thus, it may be difficult to supply the second source in a gaseous state to the wafer 200. In such a case, it may be difficult to promote a reaction to form the flowable film described above, and as a result, it may also be difficult to form the flowable film on the non-flowable film. By setting the process temperature to 0° C. or higher, it is possible to solve the problem described above. By setting the process temperature to 10° C. or higher, it is possible to sufficiently solve the problem described above. Further, by setting the process temperature to 20° C. or higher, it is possible to more sufficiently solve the problem described above.

Further, when the process temperature described above is set to be higher than 150° C., it may be difficult to promote the reaction to form the flowable film described above. In such a case, a detachment of the oligomer formed on the non-flowable film is more dominant than a growth of the oligomer. As a result, it may also be difficult to form the flowable film on the non-flowable film. By setting the process temperature to 150° C. or lower, it is possible to solve the problem described above. By setting the process temperature to 100° C. or lower, it is possible to sufficiently solve the problem described above. Further, by setting the process temperature to 60° C. or lower, it is possible to more sufficiently solve the problem described above.

Therefore, it is preferable that the process temperature is set to be 0° C. or higher and 150° C. or lower, preferably 10° C. or higher and 100° C. or lower, and more preferably 20° C. or higher and 60° C. or lower.

<Step C (PT)>

After the flowable film is formed on the non-flowable film, the output of the heater 207 is adjusted so as to change the temperature of the wafer 200 to the third temperature equal to or higher than the second temperature described above (temperature elevating step). It is preferable that the third temperature is higher than the second temperature. Then, the step C is performed when the temperature of the wafer 200 reaches and is stably maintained at the third temperature.

In the step C, the inert gas is supplied to the wafer 200 in the process chamber 201. Specifically, the valves 243e through 243g are opened such that the inert gas is supplied into the gas supply pipes 232e through 232g. A flow rate of the inert gas supplied into the gas supply pipes 232e through 232g is respectively adjusted by the MFCs 241e through 241g. Then, the inert gas whose flow rate is adjusted is supplied into the process chamber 201 through each of the nozzles 249a, 249b and 249c, and is exhausted through the exhaust port 231a. Thereby, the inert gas is supplied to the wafer 200.

For example, the process conditions in the step C are as follows:
The process temperature (third temperature): from 100° C. to 1,000° C., preferably from 200° C. to 600° C.;
The process pressure: from 10 Pa to 80,000 Pa, preferably from 200 Pa to 6,000 Pa;
The supply flow rate of the inert gas (for each gas supply pipe): from 0.01 slm to 2 slm; and
A supply time (time duration) of the inert gas: from 300 seconds to 10,800 seconds.

By performing the step C in accordance with the process conditions described above, it is possible to modify the flowable film formed on the non-flowable film. As a result, it is possible to form a modified film (which is obtained by modifying the flowable film) to fill the inside of the recess with the non-flowable film formed on the surface thereof. For example, as the modified film, the Si- and N-containing film such as the SiN film or the Si-, C- and N-containing film such as the SiCN film may be formed. Further, by discharging a surplus substance contained in the flowable film while promoting a flow of the flowable film, it is possible to densify the flowable film. Further, by setting the process temperature (third temperature) in the step C to be higher than the process temperature (first temperature) in the step A, it is possible to modify not only the flowable film but also the non-flowable film serving as a base (underlying film) of the flowable film. That is, by discharging a surplus substance contained in the non-flowable film, it is possible to densify the non-flowable film.

<After-Purge Step and Returning to Atmospheric Pressure Step>

After the step C is completed, the inert gas serving as the purge gas is supplied into the process chamber 201 through each of the nozzles 249a, 249b and 249c, and then is exhausted through the exhaust port 231a. Thereby, the inner atmosphere of the process chamber 201 is purged with the purge gas. As a result, a substance such as a residual gas and the reaction by-products remaining in the process chamber 201 is removed from the process chamber 201 (after-purge step). Thereafter, the inner atmosphere of the process chamber 201 is replaced with the inert gas (substitution by inert gas), and the inner pressure of the process chamber 201 is returned to the normal pressure (returning to atmospheric pressure step).

<Boat Unloading Step and Wafer Discharging Step>

Thereafter, the seal cap 219 is lowered by the boat elevator 115 and the lower end of the manifold 209 is opened. Then, the boat 217 with the processed wafers 200 supported therein is unloaded (transferred) out of the reaction tube 203 through the lower end of the manifold 209 (boat unloading step). After the boat 217 is unloaded, the shutter 219s is moved such that the lower end opening of the manifold 209 is sealed by the shutter 219s through the O-ring 220c (shutter closing step). The processed wafers 200 are discharged (transferred) from the boat 217 after the boat 217 is unloaded out of the reaction tube 203 (wafer discharging step).

### (3) Effects According to Present Embodiment

According to the present embodiment, it is possible to obtain one or more of the following effects.

(a) By performing the step A and the step B in this order, that is, by forming the non-flowable film at a higher temperature than the flowable film forming step before forming the flowable film on the surface of the wafer 200 (wherein the recess is provided on the surface of the wafer 200 and the oxygen-containing film is exposed on the surface of the wafer 200), it is possible to block an influence of a surface state of the oxygen-containing film serving as the base of the film formation. Thereby, it is possible to appropriately form the flowable film on the surface of the wafer 200 while suppressing an abnormal growth and an occurrence of a defective film formation on the surface of the wafer 200. As a result, it is possible to improve embedding characteristics (filling characteristics), and it is also possible to perform a void-free and seamless embedding (filling) with a high quality film.

Further, the abnormal growth described above may refer to a situation where the film to be formed on the wafer 200 grows in a so-called droplet shape (island shape) since the film to be formed on the wafer 200 is affected by the surface state of the oxygen-containing film serving as the base of the film formation, that is, affected by an OH (hydroxyl group) termination on the surface of the oxygen-containing film. The abnormal growth may reduce a thickness uniformity of the film to be formed on the wafer 200. In addition, the abnormal growth may inhibit a conformal formation of the film on the wafer 200 and may hinder embedding (filling) into the recess. Further, the abnormal growth may deteriorate a surface roughness (flatness) of the film to be formed on the wafer 200. Further, the abnormal growth may generate particles within the process chamber 201.

(b) By setting the thickness of the non-flowable film equal to or less than the thickness of the flowable film (preferably, setting the non-flowable film to be thinner than the flowable film), it is possible to suppress an occurrence of a film peeling of the non-flowable film while maintaining the fluidity of the flowable film.

For example, when the thickness of the non-flowable film is set to be less than 0.2 nm, the process of forming the flowable film may be affected by the surface state of the oxygen-containing film serving as the base of the film formation. That is, when the thickness of the non-flowable film is set to be too thin, an effect (also referred to as a “blocking effect”) of the non-flowable film in blocking the influence of the surface state of the oxygen-containing film may be insufficient. In such a case, the abnormal growth of the film on the surface of the wafer 200, that is, the defective film formation may occur.

On the other hand, by setting the thickness of the non-flowable film to 0.2 nm or more, it is possible to sufficiently block the influence of the surface state of the oxygen-containing film on the process of forming the flowable film. That is, by providing the non-flowable film with an appropriate thickness, it is possible to fully (sufficiently) exert the blocking effect of the non-flowable film in blocking the influence of the surface state of the oxygen-containing film. As a result, it possible to sufficiently suppress the abnormal growth of the film on the surface of the wafer 200 (that is, the occurrence of the defective film formation).

For example, by setting the thickness of the non-flowable film to 0.5 nm or more, it is possible to further enhance the blocking effect of the non-flowable film in blocking the influence of the surface state of the oxygen-containing film, and it is also possible to sufficiently obtain the effects described above. Further, by setting the thickness of the non-flowable film to 1.5 nm or more, it is possible to more further enhance the blocking effect of the non-flowable film in blocking the influence of the surface state of the oxygen-containing film, and it is also possible to more sufficiently obtain the effects described above.

Therefore, it is preferable that the thickness of the non-flowable film is set to be 0.2 nm or more, preferably 0.5 nm or more, and more preferably 1.5 nm or more.

For example, when the thickness of the non-flowable film is set to be greater than 10 nm, the film peeling may occur, and the film peeling may cause a generation of the particles or may cause the defective film formation. That is, when the thickness of the non-flowable film is set to be too thick, although the blocking effect described above is enhanced, the film-forming process may be adversely affected due to the film peeling.

On the other hand, by setting the thickness of the non-flowable film to 10 nm or less, it is possible to sufficiently suppress the occurrence of the film peeling, and it is also possible to suppress the generation of the particles and the occurrence of the defective film formation due to the film peeling. That is, by providing the non-flowable film with an appropriate thickness, it is possible to fully (sufficiently) suppress the occurrence of the film peeling. As aresult, it is possible to prevent adverse effects on the film-forming process (which are caused by the film peeling) from occurring.

For example, by setting the thickness of the non-flowable film to 5 nm or less, it is possible to further enhance an effect of suppressing the occurrence of the film peeling, and it is also possible to sufficiently obtain the effects described above. Further, by setting the thickness of the non-flowable film to 3 nm or less, it is possible to more further enhance the effect of suppressing the occurrence of the film peeling, and it is also possible to more sufficiently obtain the effects described above.

Therefore, it is preferable that the thickness of the non-flowable film is set to be 10 nm or less, preferably 5 nm or less, and more preferably 3 nm or less.

Taking these into consideration, for example, it is preferable that the thickness of the non-flowable film is set to be 0.2 nm or more and 10 nm or less, preferably 0.5 nm or more and 5 nm or less, and more preferably 1.5 nm or more and 3 nm or less.

(c) When the oxygen-containing film serving as the base of the film formation is the Si- and O-containing film, the Si- and O-containing film contains many OH (hydroxyl group) terminations on a surface thereof. In particular, it is possible to significantly obtain the effects described above.

(d) When the non-flowable film to be formed on the wafer 200 is the oxygen-free film, in particular, it is possible to significantly obtain the effects described above. For example, when the non-flowable film to be formed on the wafer 200 is the Si- and N-containing film or the Si-, C- and N-containing film, in particular, it is possible to significantly obtain the effects described above.

(e) When the hydrophilicity of the non-flowable film to be formed on the wafer 200 is lower than that of the oxygen-containing film serving as the base of the film formation, in particular, it is possible to significantly obtain the effects described above. Further, when the oxygen-containing film serving as the base of the film formation is the hydrophilic film and the non-flowable film to be formed on the oxygen-containing film is the non-hydrophilic film (that is, the hydrophobic film), in particular, it is possible to significantly obtain the effects described above.

(f) In the step A, by supplying the first source and the first reactant to the wafer 200 under the condition where the chemical adsorption or the thermal decomposition of the first source occurs more dominantly than the physical adsorption of the first source in a case where the first source is provided alone, it is possible to efficiently form the non-flowable film on the wafer 200.

(g) In the step A, by performing the first cycle including the step A1 and the step A2 the first predetermined number of times (m times, where m is an integer of 1 or more), it is possible to form the non-flowable film on the wafer 200 with good controllability. In addition, by performing the first cycle (wherein the step A1 and the step A2 are performed non-simultaneously) the first predetermined number of times, it is possible to form the non-flowable film on the wafer 200 with better controllability.

For example, in the step A, by performing the first cycle including the step A1 of adsorbing part of the molecular structure of the molecule of the first source onto the surface of the oxygen-containing film and the step A2 of forming the non-flowable layer by reacting the part of the molecular structure of the molecule of the first source adsorbed on the surface of the oxygen-containing film with the first reactant the first predetermined number of times, it is possible to form the non-flowable film in which the non-flowable layer formed per cycle are stacked (laminated), and it is also possible to form the non-flowable film with better controllability.

(h) Since at least one selected from the group of the first source and the first reactant contains the alkyl group, that is, the first material contains the alkyl group, it is possible to efficiently generate a reaction to form the non-flowable film on the surface of the wafer 200. Further, since the first material contains the alkyl group, it is possible to further enhance the blocking effect of the non-flowable film in blocking the influence of the surface state of the oxygen-containing film.

(i) In the step B, by supplying the second source, the second reactant and the third reactant to the wafer 200 under the condition where the physical adsorption of the second source occurs more dominantly than the chemical adsorption of the second source without thermally decomposing the second source in a case where the second source is provided alone, it is possible to efficiently form the flowable film on the wafer 200.

(j) In the step B, by performing the second cycle including the step B1, the step B2 and the step B3 the second predetermined number of times (n times, where n is an integer of 1 or more), it is possible to form the flowable film on the wafer 200 with the good controllability.

(k) In the step B, the oligomer containing the element or the elements contained in at least one selected from the group of the second source, the second reactant and the third reactant can be generated, grown, and flowed. Thereby, it is possible to form an appropriate flowable film on the non-flowable film. Further, the oligomer is generated in the step B while the oligomer is not generated in the step A.

(l) In the step B, by making the molecular structure of the second reactant and the molecular structure of the third reactant different, it is possible to assign different roles to each reactant. For example, when the amine-based gas is used as the second reactant, the second reactant acts as a catalyst in the step B1. By performing the step B1 wherein the second reactant acts as the catalyst, it is possible to activate the second source physically adsorbed on the surface of the wafer 200. Further, for example, when the hydrogen nitride-based gas is used as the third reactant, the third reactant acts as a nitrogen source. Thereby, it is possible to contain nitrogen (N) in the flowable film.

(m) After the flowable film is formed on the non-flowable film, in the step C, by performing the post-treatment to the wafer 200 at the third temperature higher than the second temperature, it is possible to promote the flow of the flowable film, and it is possible to improve the embedding characteristics (filling characteristics) of the film formed inside the recess.

For example, in the step C, by discharging the surplus substance contained in the flowable film while promoting the flow of the flowable film, it is possible to densify the flowable film. As a result, it is possible to improve the embedding characteristics (filling characteristics) of the film formed to fill the inside of the recess. Further, it is possible to reduce an impurity concentration of the film formed to fill the inside of the recess, and it is also possible to increase a density of the film. Thereby, it is possible to improve the wet etching resistance of the film formed within the recess.

For example, in the step C, by supplying the inert gas to the wafer 200, it is possible to promote the flow of the flowable film, and it is also possible to improve the embedding characteristics (filling characteristics) of the film formed inside the recess. For example, it is possible to reduce the impurity concentration of the film formed to fill the inside of the recess, and it is also possible to increase the density of the film. Thereby, it is possible to improve the wet etching resistance of the film formed within the recess.

(n) By setting the molecular structure of the first source to be the same as the molecular structure of the second source and the molecular structure of the first reactant to be the same as the molecular structure of one of the second reactant and the third reactant, that is, by forming the non-flowable film and the flowable film by using the same source and the same reactant in the step A and the step B, it is possible to simplify a structure of a material supplier (which is material supply structure or a material supply system) by, for example, reducing the number of supply lines, and it is also possible to suppress an increase in an apparatus cost.

(o) When a silicon-containing source is used as the first source and the second source, and the N- and H-containing reactant or the C-, N- and H-containing reactant is used as the first reactant, the second reactant and third reactant, in particular, it is possible to significantly obtain the effects described above.

(p) By performing the step A and the step B in the same process chamber (that is, “in-situ”), it is possible to form the non-flowable film and the flowable film continuously, and it is also possible to maintain an interface between the non-flowable film and the flowable film in a clean state. Thereby, it is possible to suppress deterioration of the characteristics of the film and electrical characteristics of the film. On the other hand, when the non-flowable film and the flowable film are formed in different process chambers (that is, “ex-situ”), since the non-flowable film is exposed to an atmosphere outside the process chamber, for example, an atmospheric air, a moisture and impurities contained in the atmospheric air may be introduced into the interface between the non-flowable film and the flowable film. Therefore, it may be difficult to maintain the interface in the clean state. In such a case, the characteristics of the film and the electrical characteristics of the film may deteriorate due to the interface in such a state.

(q) By forming the non-flowable film on the surface of the wafer 200 and a surface of the recess (that is, inside the recess) in the step A, and by forming the flowable film on the non-flowable film formed on the surface of the wafer 200 and inside the recess and filling the recess with the flowable film in the step B, it is possible to obtain the effects described above. As a result, it is possible to improve the embedding characteristics (filling characteristics) while suppressing the abnormal growth of the film on the surface of the wafer 200, and it is also possible to perform the void-free and seamless embedding (filling) with the high quality film.

(r) According to the present embodiment, a series of processes can be performed in a non-plasma atmosphere. Thereby, it is possible to prevent a plasma damage to the wafer 200 and the like.

(s) It is possible to obtain substantially the same effects as described above even when the various sources, the various reactants and the various inert gases described above are used in the step A and the step B. It is also possible to obtain substantially the same effects as described above even when a sequential order of supplying the gases in each cycle is changed. Further, it is possible to obtain substantially the same effects as described above even when the various inert gases described above are used in the step C.

### Second Embodiment of Present Disclosure

Subsequently, the second embodiment of the technique of the present disclosure will be described in detail mainly with reference to FIG. 5.

As shown in FIG. 5 and an exemplary process sequence of the substrate processing according to the present embodiment shown below, in the step B, instead of the second cycle, a third cycle including a step B4 of simultaneously supplying the second source and the second reactant to the wafer 200 and the step B3 of supplying the third reactant to the wafer 200 may be performed the second predetermined number of times (n times, n is an integer equal to or greater than 1). In the third cycle of the exemplary process sequence of the substrate processing according to the present embodiment, the step B4 and the step B3 are performed non-simultaneously.

(first source→first reactant)×m→(second source+second reactant→third reactant)×n→PT

According to the present embodiment, it is possible to obtain substantially the same effects as in the first embodiment described above. Further, according to the present embodiment, by simultaneously supplying the second source and the second reactant, it is possible to improve a cycle rate, and thereby it is also possible to increase a productivity of the substrate processing. The process conditions when simultaneously supplying the second source and the second reactant may be substantially the same as the process conditions when supplying the second reactant in the step B2 of the first embodiment described above.

### Third Embodiment of Present Disclosure

Subsequently, the third embodiment of the technique of the present disclosure will be described in detail mainly with reference to FIG. 6.

As shown in FIG. 6 and an exemplary process sequence of the substrate processing according to the present embodiment shown below, in the step B, instead of the second cycle, a fourth cycle including the step B4 of simultaneously supplying the second source and the second reactant to the wafer 200, the step B3 of supplying the third reactant to the wafer 200 and the step B2 of supplying the second reactant to the wafer 200 may be performed the second predetermined number of times (n times, n is an integer equal to or greater than 1). In the fourth cycle of the exemplary process sequence of the substrate processing according to the present embodiment, the step B4, the step B3 and the step B2 are performed non-simultaneously.

(first source→first reactant)×m→(second source+second reactant→third reactant→second reactant)×n→PT

According to the present embodiment, it is possible to obtain substantially the same effects as in the first embodiment described above. Further, according to the present embodiment, for example, when the amine-based gas is used as the second reactant, the second reactant supplied in a first execution of the fourth cycle acts as the catalyst. Thereby, it is possible to activate the second source. Further, the second reactant supplied in a second execution of the fourth cycle can act as a gas for removing the by-products generated during the film-forming process, that is, as a reactive purge gas. The process conditions when supplying the second reactant in the present embodiment may be substantially the same as the process conditions when supplying the second reactant in the step B2 of the first embodiment described above.

### Other Embodiments of Present Disclosure

While the technique of the present disclosure is described in detail by way of the embodiments described above, the technique of the present disclosure is not limited thereto. The technique of the present disclosure may be modified in various ways without departing from the scope thereof.

For example, when a source containing silicon (Si), carbon (C) and nitrogen (N) such as the alkylaminosilane-based gas is used as the first source, in the step A, the first source alone may be used as the first material without using the first reactant. That is, in the step A, the first source alone may be supplied to the substrate (that is, the wafer 200) provided with the recess on the surface thereof and where the oxygen-containing film is exposed without supplying the first reactant at the first temperature. That is, the first source alone may be supplied as the first material, and the inert gas may be simultaneously supplied with first source. For example, the process procedure and the process conditions when supplying the first source alone may be substantially the same as those of the step A1 of the embodiments described above. Even in such a case, by performing the step A, it is possible to form the non-flowable film on the surface of the substrate, and it is possible to obtain substantially the same effects as in the embodiments described above.

For example, in such a case, when the first source is supplied to the substrate under a condition where the adsorption of the first source onto the surface of the substrate is self-limited, part of the molecular structure of the molecule of the first source is adsorbed (chemical adsorption) on the surface of the oxygen-containing film. By performing the step A in such a state, the non-flowable film containing silicon, carbon and nitrogen with a thickness of one monolayer is formed on the surface of the substrate. Furthermore, in such a case, when the first source is supplied to the substrate under a condition where the adsorption of the first source onto the surface of the substrate is not self-limited, the first source decomposes. By performing the step A in such a state, the non-flowable film containing silicon, carbon and nitrogen with a thickness of more than one monolayer is formed on the surface of the substrate.

For example, as the reactants (that is, the first reactant, the second reactant and the third reactant), instead of or in addition to the N- and H-containing gas or the C-, N- and H-containing gas, a gas containing carbon (C) and hydrogen (H) such as ethylene (C₂H₄) gas, acetylene (C₂H₂) gas, and propylene (C₃H₆) gas or a gas containing boron (B) and hydrogen (H) such as diborane (B₂H₆) gas and trichloroborane (BCl₃) may be used. Then, by the process sequence described above using the reactants exemplified above, instead of or in addition to the SiN film or the SiCN film described above, an oxygen-free film containing silicon such as a silicon carbide film (SiC film), a silicon boronitride film (SiBN film) and a silicon borocarbonitride film (SiBCN film) may also be formed on the substrate. For example, the process procedure and the process conditions when supplying the sources and the reactants in such a case may be substantially the same as those of the steps of the embodiments described above. For example, in such a case, a type of the non-flowable film may be different from that of the flowable film. For example, when the SiN film, the SiCN film or the like is formed as the flowable film, instead of or in addition to the SiN film or the SiCN, a film such as the SiC film, the SiBN film and the SiBCN film may be formed as the non-flowable film. Even in such a case, it is possible to obtain substantially the same effects as in the embodiments described above.

For example, the technique of the present disclosure may be preferably applied when a source gas containing a metal element such as aluminum (Al), titanium (Ti), hafnium (Hf), zirconium (Zr), tantalum (Ta), molybdenum (Mo) and tungsten (W) is used as the sources (that is, the first source and the second source) and when a film containing the metal element such as an aluminum nitride film (AlN film), a titanium nitride film (TiN film), a hafnium nitride film (HfN film), a zirconium nitride film (ZrN film), a tantalum nitride film (TaN film), a molybdenum nitride film (MoN), a tungsten nitride film (WN film), an aluminum carbonitride film (AlCN film), a titanium carbonitride film (TiCN film), a hafnium carbonitride film (HfCN film), a zirconium carbonitride film (ZrCN film), a tantalum carbonitride film (TaCN film), a molybdenum carbonitride film (MoCN film), a tungsten carbonitride film (WCN film), a titanium aluminum nitride film (TiAlN film), a titanium aluminum carbonitride film (TiAlCN film) and a titanium aluminum carbide film (TiAlC film). For example, the process procedure and the process conditions when supplying the sources and the reactants in such a case may be substantially the same as those of the steps of the embodiments described above. For example, even in such a case, the type of the non-flowable film may be different from that of the flowable film. For example, when the SiN film, the SiCN film or the like is formed as the flowable film, a film such as the AlN film, the TiN film, the HfN film, the ZrN film, the TaN film, the MoN film, the WN film, the AlCN film, the TiCN film, the HfCN film, the ZrCN film, the TaCN film, the MoCN, the WCN film, the TiAlN film, the TiAlCN film and the TiAlC film may be formed as the non-flowable film. Even in such a case, it is possible to obtain substantially the same effects as in the embodiments described above.

For example, in the post-treatment (PT), a hydrogen-containing gas such as hydrogen (H₂) gas may be supplied to the substrate, a nitrogen-containing gas such as the NH₃ gas, that is, the N- and H-containing gas may be supplied to the substrate, or an oxygen-containing gas such as H₂O gas, that is, a gas containing oxygen and hydrogen (hereinafter, also be referred to as an “O- and H-containing gas”). For example, O₂ gas may be supplied as the oxygen-containing gas. That is, in the PT, at least one selected from the group of the nitrogen-containing gas, the hydrogen-containing gas, the N- and H-containing gas, the oxygen-containing gas and the O and H-containing gas may be supplied to the substrate.

For example, the process conditions when the hydrogen-containing gas is supplied in the PT are as follows:
A supply flow rate of the hydrogen-containing gas: from 0.01 slm to 3 slm; and
The process pressure: from 10 Pa to 1,000 Pa, preferably from 200 Pa to 800 Pa.

The other process conditions when the hydrogen-containing gas is supplied in the PT may be set to be substantially the same as those in the step C described above.

For example, the process conditions when the N- and H-containing gas is supplied in the PT are as follows:
A supply flow rate of the N- and H-containing gas: from 10 sscm to 10,000 sccm; and
The process pressure: from 10 Pa to 6,000 Pa, preferably from 200 Pa to 2,000 Pa.

The other process conditions when the N- and H-containing gas is supplied in the PT may be set to be substantially the same as those in the step C described above.

For example, the process conditions when the oxygen-containing gas is supplied in the PT are as follows:
A supply flow rate of the oxygen-containing gas: from 10 seem to 10,000 sccm; and
The process pressure: from 10 Pa to 90,000 Pa, preferably from 20,000 Pa to 80,000 Pa.

The other process conditions when the oxygen-containing gas is supplied in the PT may be set to be substantially the same as those in the step C described above.

Even in such cases, it is possible to obtain substantially the same effects as in the first embodiment described above. For example, when performing the PT in a hydrogen-containing gas atmosphere or in an N- and H-containing gas atmosphere, it is possible to increase the fluidity of an oligomer-containing layer and also possible to improve the embedding characteristics (filling characteristics) of the film formed inside the recess as compared with a case where the PT is performed in an inert gas atmosphere. Further, when performing the PT in the hydrogen-containing gas atmosphere or in the N- and H-containing gas atmosphere, it is possible to reduce the impurity concentration of the film formed inside of the recess, to increase the density of the film and to improve the wet etching resistance as compared with the case where the PT is performed in the inert gas atmosphere. Further, when performing the PT in the N- and H-containing gas atmosphere, it is possible to enhance the effects as compared with a case where the PT is performed in the hydrogen-containing gas atmosphere. For example, when performing the PT in an oxygen-containing gas atmosphere, it is possible to include oxygen in the film obtained by modifying the oligomer-containing layer. That is, the film where oxygen is included serves as a silicon oxycarbonitride film (SiOCN film), which is a film containing silicon, oxygen, carbon and nitrogen.

For example, the technique of the present disclosure is not limited to a case where the oxygen-containing film exposed on the surface of the substrate is a silicon oxide film (SiO film). For example, the technique of the present disclosure may also be applied when a film such as a silicon oxynitride film (SiON film), a silicon oxycarbide film (SiOC film) and a silicon oxycarbonitride film (SiOCN film) is used as the oxygen-containing film. That is, when the OH termination exists on the surface of the oxygen-containing film exposed on the surface of the substrate, the technique of the present disclosure may also be applied, and it is possible to obtain substantially the same effects as in the embodiments described above.

Examples in which the film such as the SiN film, the SiCN film and the SiOCN film is formed to fill the recess formed on the surface of the substrate are described above. However, the technique of the present disclosure is not limited thereto. For example, the technique of the present disclosure may also be applied when a film such as the SiO film, the SiOC film and a silicon film (Si film) is formed to fill the recess formed on the surface of the substrate by appropriately combining the first material, the second material and the gas used in the PT. Even in such a case, it is possible to obtain substantially the same effects as in the embodiments described above.

For example, the technique of the present disclosure may also be preferably applied when forming a structure such as an STI (Shallow Trench Isolation), a PMD (Pre-Metal Dielectric), an IMD (Inter-Metal Dielectric), an ILD (Inter-Layer Dielectric) and GCF (Gate Cut Fill).

It is preferable that recipes used in the substrate processing are prepared individually in accordance with contents of the substrate processing and are written and stored in the memory 121c via an electric communication line or the external memory 123. When starting the substrate processing, it is preferable that the CPU 121a selects an appropriate recipe among the recipes stored in the memory 121c in accordance with the contents of the substrate processing. Thus, various films of different composition ratios, qualities and thicknesses can be formed in a highly reproducible manner by using a single substrate processing apparatus. In addition, since a burden on an operating personnel of the substrate processing apparatus can be reduced, various processes of the substrate processing can be performed quickly while avoiding a malfunction of the substrate processing apparatus.

The recipe described above is not limited to creating a new recipe. For example, the recipe may be prepared by changing an existing recipe stored (or installed) in the substrate processing apparatus in advance. When changing the existing recipe to a new recipe, the new recipe may be installed in the substrate processing apparatus via the electric communication line or the recording medium in which the new recipe is stored. Further, the existing recipe already stored in the substrate processing apparatus may be directly changed to the new recipe by operating the input/output device 122 of the substrate processing apparatus.

For example, the embodiments and the modified examples described above are described by way of an example in which a batch type substrate processing apparatus capable of simultaneously processing a plurality of substrates is used to form the film. However, the technique of the present disclosure is not limited thereto. For example, the technique of the present disclosure may be preferably applied when a single wafer type substrate processing apparatus capable of simultaneously processing one or several substrates is used to form the film. For example, the embodiments and the modified examples described above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

The process procedure and the process conditions of each process using the substrate processing apparatuses exemplified above may be substantially the same as those of the embodiments or the modified examples described above. Even in such a case, it is possible to obtain substantially the same effects as in the embodiments or the modified examples described above.

Further, the embodiments and the modified examples described above may be appropriately combined. The process procedure and the process conditions of each combination thereof may be substantially the same as those of the embodiments or the modified examples described above.

### Example of Present Disclosure

As an example of the embodiments of the present disclosure, the film-forming process is performed on the wafer (wherein the recess is provided on the surface of the wafer and the oxygen-containing film is exposed on the surface of the wafer) by performing the process sequence of the first embodiment (that is, by performing the non-flowable film forming step, the flowable film forming step and the post-treatment) using the substrate processing apparatus shown in FIG. 1. The process conditions in each step for the example of the embodiments are set to predetermined conditions within a range of the process conditions in each step of the process sequence of the first embodiment.

As a comparative example, the film-forming process is performed on the wafer (wherein the recess is provided on the surface of the wafer and the oxygen-containing film is exposed on the surface of the wafer) by performing the flowable film forming step and the post-treatment of the process sequence of the first embodiment using the substrate processing apparatus shown in FIG. 1. The process conditions in each step for the comparative example are set to predetermined conditions within a range of the process conditions in each step of the process sequence of the first embodiment.

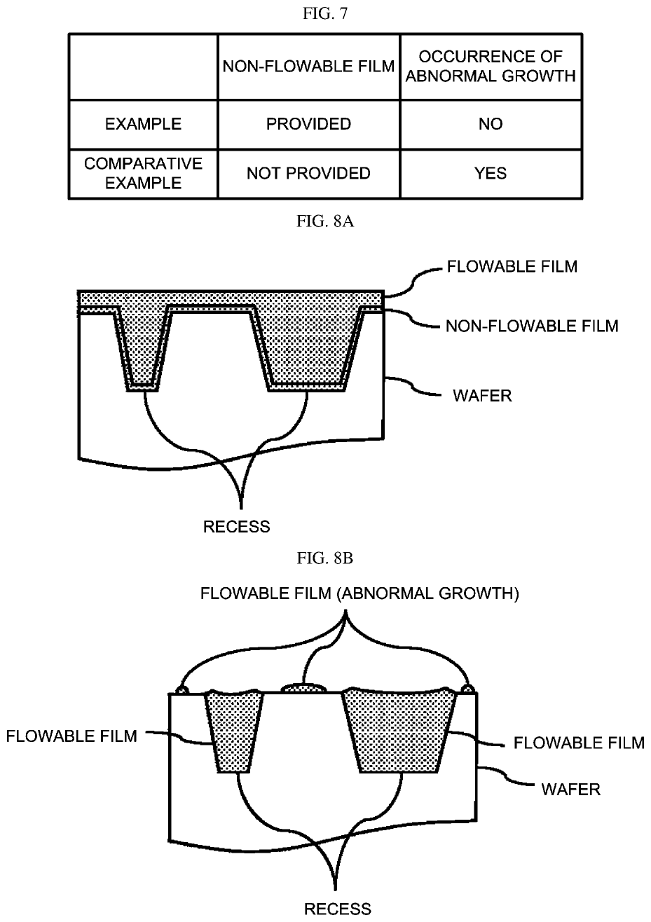

Then, the surfaces of the wafers after the film-forming process in the example of the embodiments and the comparative example are observed to confirm an occurrence of the abnormal growth. The results are shown in FIGS. 7, 8A and 8B. As shown in FIGS. 7 and 8A, in the example in which the non-flowable film is formed before forming the flowable film, no abnormal growth of the flowable film is observed. On the other hand, as shown in FIGS. 7 and 8B, in the comparative example in which the non-flowable film is not formed before forming the flowable film, the abnormal growth of the flowable film is confirmed.

According to some embodiments of the present disclosure, it is possible to improve the characteristics of the film formed on the substrate provided with the recess on the surface thereof.

What is claimed is:

1. A processing method comprising:
(a) forming a non-flowable film on a surface of a substrate on which a recess is provided and an oxygen-containing film is exposed by supplying a first material to the substrate at a first temperature; and
(b) forming a flowable film on the non-flowable film by supplying a second material to the substrate at a second temperature lower than the first temperature.

2. The processing method of claim 1, wherein a thickness of the non-flowable film is set to be equal to or less than a thickness of the flowable film.

3. The processing method of claim 1, wherein a thickness of the non-flowable film is set to be 0.2 nm or more and 10 nm or less.

4. The processing method of claim 1, wherein the oxygen-containing film comprises a film containing silicon and oxygen.

5. The processing method of claim 1, wherein the non-flowable film comprises an oxygen-free film.

6. The processing method of claim 1, wherein the non-flowable film comprises a film containing silicon and nitrogen.

7. The processing method of claim 1, wherein the non-flowable film comprises a film containing silicon, carbon and nitrogen.

8. The processing method of claim 1, wherein a hydrophilicity of the non-flowable film is set to be lower than that of the oxygen-containing film.

9. The processing method of claim 1, wherein the oxygen-containing film is a hydrophilic film and the non-flowable film is a non-hydrophilic film.

10. The processing method of claim 1, wherein the first material comprises a first source and a first reactant, and
wherein, in (a), the first source and the first reactant are supplied to the substrate under a condition where a chemical adsorption or a thermal decomposition of the first source occurs more dominantly than a physical adsorption of the first source in a case where the first source is provided alone.

11. The processing method of claim 10, wherein, in (a), a cycle comprising (a1) supplying the first source to the substrate and (a2) supplying the first reactant to the substrate is performed a predetermined number of times.

12. The processing method of claim 11, wherein a part of a molecular structure of a molecule of the first source is adsorbed onto a surface of the oxygen-containing film in (a1), and the part of the molecular structure of the molecule of the first source adsorbed on the surface of the oxygen-containing film is caused to react with the first reactant to form a non-flowable layer in (a2).

13. The processing method of claim 10, wherein at least one selected from the group of the first source and the first reactant contains an alkyl group.

14. The processing method of claim 1, wherein the first material contains an alkyl group.

15. The processing method of claim 10, wherein the second material comprises a second source, a second reactant and a third reactant, and
wherein, in (b), the second source, the second reactant and the third reactant are supplied to the substrate under a condition where a physical adsorption of the second source occurs more dominantly than a chemical adsorption of the second source without hardly thermally decomposing the second source in a case where the second source is provided alone.

16. The processing method of claim 15, wherein, in (b), a cycle comprising (b1) supplying the second source to the substrate, (b2) supplying the second reactant to the substrate and (b3) supplying the third reactant to the substrate is performed a predetermined number of times.

17. The processing method of claim 15, wherein, in (b), an oligomer-containing film is formed as the flowable film on the non-flowable film by generating, growing and flowing an oligomer containing an element or elements contained in at least one selected from the group of the second source, the second reactant and the third reactant.

18. The processing method of claim 1, further comprising
(c) modifying the flowable film by performing a post-treatment to the substrate after the flowable film is formed on the non-flowable film at a third temperature higher than the second temperature.

19. The processing method of claim 15, wherein a molecular structure of the first source is same as that of the second source, and a molecular structure of the first reactant is same as that of the second reactant or that of the third reactant.

20. The processing method of claim 15, wherein the first source and the second source comprise a silicon-containing source, and the first reactant, the second reactant, and third reactant comprise a reactant containing nitrogen and hydrogen or a reactant containing carbon, nitrogen and hydrogen.

21. The processing method of claim 1, wherein (a) and (b) are performed in a same process chamber.

22. The processing method of claim 1, wherein the non-flowable film is formed on the surface of the substrate and a surface of the recess in (a), and the recess is filled with the flowable film by forming the flowable film on the non-flowable film formed on the surface of the substrate and inside the recess in (b).

23. A method of manufacturing a semiconductor device, comprising the processing method of claim 1.

24. A processing apparatus comprising:
a first material supplier through which a first material is supplied to a substrate;
a second material supplier through which a second material is supplied to the substrate;
a heater configured to heat the substrate; and
a controller configured to be capable of controlling the first material supplier, the second material supplier and the heater so as to perform:
(a) forming a non-flowable film on a surface of the substrate on which a recess is provided and an oxygen-containing film is exposed by supplying the first material to the substrate at a first temperature; and
(b) forming a flowable film on the non-flowable film by supplying the second material to the substrate at a second temperature lower than the first temperature.

25. A non-transitory computer-readable recording medium storing a program that causes a processing apparatus, by a computer, to perform:
(a) forming a non-flowable film on a surface of a substrate on which a recess is provided and an oxygen-containing film is exposed by supplying a first material to the substrate at a first temperature; and
(b) forming a flowable film on the non-flowable film by supplying a second material to the substrate at a second temperature lower than the first temperature.
